(19) United States
(12) Patent Application Publication
(10) Pub. No.: US 2026/0214826 A1
(43) Pub. Date: Jul. 23, 2026

(54) CABLE MANAGEMENT SYSTEM

(71) Applicant: Illinois Tool Works Inc., Glenview, IL (US)

(72) Inventors: Daniel M. Miranowski, Bloomington, MN (US); Johnson W. Glass, Coon Rapids, MN (US); William G. Hughes, Ramsey, MN (US); Adam J. Sauter, Maple Grove, MN (US); Griffin E. Rustad, Minneapolis, MN (US)

(21) Appl. No.: 19/455,216

(22) Filed: Jan. 21, 2026

Related U.S. Application Data
(60) Provisional application No. 63/748,012, filed on Jan. 22, 2025.

(51) Int. Cl. H05K 7/14

(52) U.S. Cl. CPC H05K 7/1447

(57) ABSTRACT

A cable management system configured for attachment to a rack frame of an electronic equipment rack includes a cable management frame including a pair of side vertical frame members extending along a vertical axis and a top horizontal member connected to top ends of the side vertical members, a plurality of cable supports connected between the side vertical members and distributed from each other along the vertical axis between the top ends and bottom ends of the side vertical members, each cable support including a horizontal support extending between the side vertical members and a plurality of cable dividers attached to and distributed along the horizontal support, and a cable management housing panel attached to the cable management frame and covering an opening to a cable management chamber extending between the side vertical members and containing the cable supports.

### CROSS-REFERENCE TO RELATED APPLICATION(S)

The present application is based on and claims the benefit of U.S. provisional patent application Serial No. 63/748,012, filed January 22, 2025, the content of which is hereby incorporated by reference in its entirety.

### BACKGROUND

Electronic equipment racks are used to store electronic components having a standardized width in a vertical stack, such as network switches and other electronic components. Advancements of such electronic components often result in the components having a smaller height, which allows a larger number of the components to be stored in a given equipment rack. Each electronic component may each require a large number of wiring connections, such as 64 connections. As a result, a rack of 10 components may need to handle 640 or more separate cables.

Some equipment racks are configured to house the electronic equipment within a temperature-controlled environment, in which cooling air is circulated to prevent the equipment from overheating. However, the large number of cables can prevent the proper circulation of the air and lead to equipment overheating.

Accordingly, the large number of cables that must be routed through an equipment rack can lead to problems in organizing the cables, properly supporting the cables, and controlling the temperature of the electronic components.

### SUMMARY

Embodiments of the present disclosure are directed to a cable management system configured for attachment to an electronic equipment rack to facilitate improved air flow, installation time, support and/or organization of cables that connect to electronic equipment supported in the rack. Additional embodiments relate to an electronic equipment housing system that includes the cable management system and a method of installing a cable management system to an electronic equipment rack, and other embodiments.

One example of the cable management system includes a cable management frame including a pair of side vertical frame members extending along a vertical axis and a top horizontal member connected to top ends of the side vertical members, a plurality of cable supports connected between the side vertical members and distributed from each other along the vertical axis between the top ends and bottom ends of the side vertical members, each cable support including a horizontal support extending between the side vertical members and a plurality of cable dividers attached to and distributed along the horizontal support, and a cable management housing panel attached to the cable management frame and covering an opening to a cable management chamber extending between the side vertical members and containing the cable supports.

In one embodiment, the cable management frame includes a bottom member extending between the bottom ends of the side vertical members.

In one embodiment, the bottom member is pivotably attached to one of the side vertical members.

In one embodiment, opposing ends of each horizontal support are attached to one of the side vertical members.

In one embodiment, each cable divider has a convex shape and is oriented in a plane that is parallel to the vertical axis.

In one embodiment, each cable divider includes a first cable support member extending from the horizontal support toward the panel, and a second cable support member extending from the horizontal support away from the panel.

One example of the electronic equipment housing system includes an electronic equipment rack and a cable management system. The electronic equipment rack includes a rack frame configured to support a plurality of rack-mountable electronic devices in a stacked relationship along a vertical axis within a rack chamber. The cable management system includes a cable management frame attached to the rack frame, the cable management frame including a pair of side vertical members extending along the vertical axis and a top horizontal member connected to top ends of the of the side vertical members, a plurality of cable supports connected between the side vertical members and distributed from each other along the vertical axis between the top ends and bottom ends of the side vertical members, each cable support including a horizontal support extending between the side vertical members and a plurality of cable dividers attached to and distributed along the horizontal support, and a cable management housing panel attached to the cable management frame and covering an opening to a cable management chamber extending between the side vertical members and containing the cable supports.

In one embodiment, the rack frame includes a plurality of vertical frame members extending along the vertical axis within the rack chamber, and a plurality of housing panels attached to the rack frame. The housing panels including a front housing panel covering a front side of the rack chamber, a rear housing panel covering a rear side of the rack chamber that is opposite the front side, a top housing panel covering a top side of the rack chamber and extending between the front and rear housing panels, a bottom housing panel covering a bottom side of the rack chamber that is opposite the top side and extending between the front and rear housing panels and a side housing panel covering a first side of the rack chamber and extending between the front, rear, top and bottom housing panels.

In one embodiment, the cable management frame is attached to the rack frame on a second side of the rack chamber that is opposite the first side.

In one embodiment, the cable management frame extends between the front, rear, top and bottom housing panels.

In one embodiment, the electronic equipment rack includes a wheeled base supporting the rack frame, and the bottom ends of the side vertical members are positioned above the wheeled base along the vertical axis.

In one embodiment, the front housing panel is configured to pivot relative to the rack frame.

In one embodiment, the cable management frame includes a bottom member extending between the bottom ends of the side vertical members.

In one embodiment, the bottom member is pivotably attached to one of the side vertical members.

In one embodiment, the top member is pivotably attached to one of the side vertical members.

In one embodiment, opposing ends of each horizontal support are attached to one of the side vertical members and each cable divider has a convex shape and is oriented in a plane that is parallel to the vertical axis.

In one embodiment, each cable divider includes a first cable support member extending from the horizontal support toward the panel and a second cable support member extending from the horizontal support away from the panel.

In an example method of installing a cable management system to an electronic equipment rack, the electronic equipment rack includes a rack frame configured to support a plurality of rack-mountable electronic devices in a stacked relationship along a vertical axis within a rack chamber. In the method, a cable management frame assembly of the cable management system is attached to the rack frame. The cable management frame assembly includes a cable management frame comprising a pair of side vertical members extending along the vertical axis and a top horizontal member connected to top ends of the side vertical members, and a plurality of cable supports connected between the side vertical members and distributed from each other along the vertical axis between the top ends and bottom ends of the side vertical members, each cable support including a horizontal support extending between the side vertical members and a plurality of cable dividers attached to and distributed along the horizontal support. An opening to an interior of the cable management frame extending between the side vertical members and containing the cable supports is covered by attaching a cable management housing panel to the cable management frame.

In one embodiment, the electronic equipment rack includes a plurality of vertical frame members extending along the vertical axis within the rack chamber, and a plurality of housing panels attached to the rack frame. The housing panels include a front housing panel covering a front side of the rack chamber, a rear housing panel covering a rear side of the rack chamber that is opposite the front side, a top housing panel covering a top side of the rack chamber and extending between the front and rear housing panels, a bottom housing panel covering a bottom side of the rack chamber that is opposite the top side and extending between the front and rear housing panels, and a first side housing panel covering a first side of the rack chamber and extending between the front, rear, top and bottom housing panels.

In one embodiment, attaching the cable management frame assembly to the rack frame includes attaching the cable management frame assembly to the rack frame on a second side of the rack chamber that is opposite the first side.

In one embodiment, the method includes supporting with the rack frame a plurality of electronic devices in a stacked manner along the vertical axis within the rack chamber, and routing each of a plurality of cables to one of the electronic devices along a vertical cable channel extending along the vertical axis between pairs of the cable dividers of a plurality of the cable supports and along a horizontal cable channel over a plurality of the cable dividers of one of the cable supports to the electronic device.

In one embodiment, attaching the cable management frame assembly to the rack frame includes removing a second side housing panel covering the second side of the rack chamber and extending between the front, rear, top and bottom housing panels, and attaching the cable management frame assembly to the rack frame on the second side of the rack chamber.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

FIG. 1 is an isometric view of an example electronic equipment rack that includes a cable management system, in accordance with embodiments of the present disclosure.

FIG. 2 is a simplified exploded view of the equipment rack and cable management system of FIG. 1, in accordance with embodiments of the present disclosure.

FIG. 3 is a simplified top view of the rack of FIGS. 1 and 2 with a top housing panel removed, in accordance with embodiments of the present disclosure.

FIGS. 4 and 5 are simplified front views of example electronic equipment racks, in accordance with embodiments of the present disclosure.

FIG. 6 is a front view of the cable management system, in accordance with embodiments of the present disclosure.

FIG. 7 is a side view of an example of a cable support, in accordance with embodiments of the present disclosure.

FIG. 8 is an isometric view of an example electronic equipment rack, in accordance with the prior art.

FIGS. 9 and 10 are front views of electronic equipment rack examples, in accordance with the prior art.

### DETAILED DESCRIPTION OF ILLUSTRATIVE EMBODIMENTS

Embodiments of the present disclosure are described more fully hereinafter with reference to the accompanying drawings. Elements that are identified using the same or similar reference characters refer to the same or similar elements. The various embodiments of the present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art.

Embodiments of the present disclosure relate to electronic equipment rack cable management and, more particularly, to a cable management system that may be used with an electronic equipment rack to facilitate improved cable organization and support in a manner that allows for improved air circulation for the supported electronic equipment.

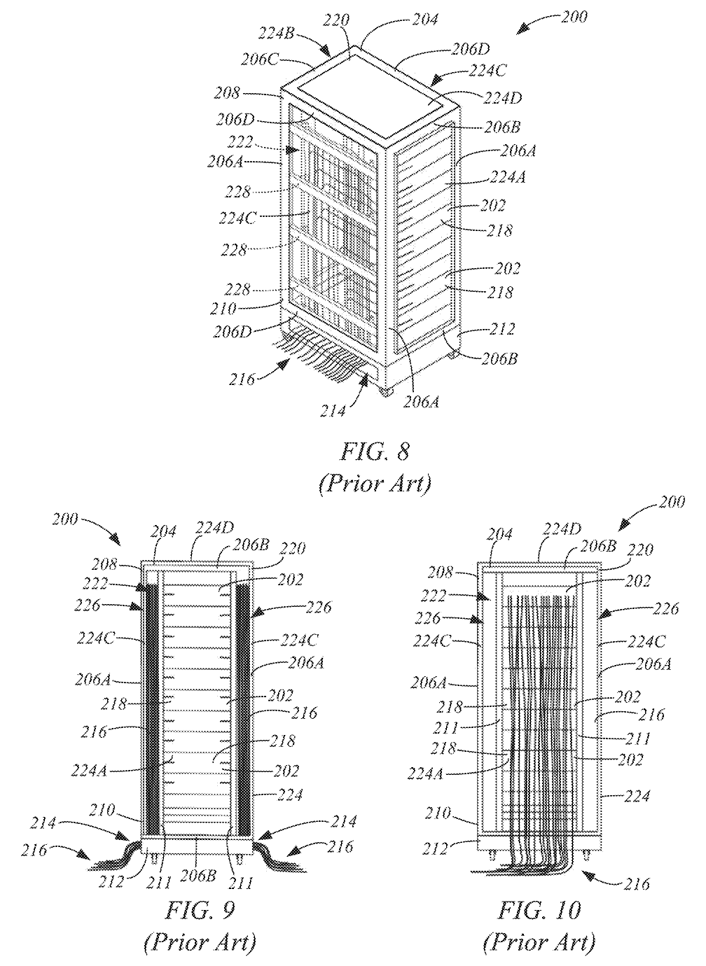

Example electronic equipment racks 200 in accordance with the prior art are shown in FIGS. 8-10. FIG. 8 is an isometric view of an example electronic equipment rack 200 and FIGS. 9 and 10 are front views of the electronic equipment rack 200.

The electronic equipment racks 200 are each configured to store electronic components 202, such as network switches, power entry panels, etc., in a stacked manner through attachment of the components 202 to a rack frame 204. The rack frame 204 may include vertical frame members 206A, opposing front and rear horizontal frame members 206B and 206C, and/or opposing side horizontal frame members 206D that extend between the vertical frame members 206A at a top side 208 and a bottom side 210.

The electronic components 202 typically have a standardized width that allows them to be rack mounted, such as between the vertical frame members 206A of the rack frame 204 or other supports, such as the supports 211 shown in FIGS. 9 and 10, which eliminates the need for shelving. A wheeled base or plinth 212 may support the rack frame 204 and include one or more cable ports 214, through which cables 216 may be fed to the components 202, such as to a connections interface 218 located on a front side of the components 202.

Each rack 200 may include a housing 220 that defines rack chamber 222, in which the components 202 are contained. The housing 220 may be formed by housing panels 224 that attach to the rack frame 204 and close openings between the frame members 206 to substantially enclose the components 202. For example, the conventional rack 200 may include a front housing panel 224A, a rear housing panel 224B, side panels 224C, and a top panel 224D. A bottom of the housing 220 may be formed by the base 212. The front housing panel 224A may be in the form of a transparent door through which the connections interface 218 of the components 202 may be accessed, such as to connect the one or more cables 216 to the interfaces 218.

The housing 220 may be used to prevent unauthorized access to the components (e.g., lockable door 224A) and to protect the components 202 from environmental conditions (e.g., dust). Each rack 200 may also include a temperature control system (not shown) to prevent the components from overheating, such as through the circulation of ambient or cooled air through open spaces 226 of the rack chamber 222, which may extend along the sides of the components 202, for example, as shown in FIGS. 9 and 10.

Advancements have allowed the electronic components 202 to be formed smaller resulting in an increase in the number of the components 202 that can be stored within the rack chamber 222 of the equipment racks 200. Additional advancements may allow the components 202 to include more cable connections (e.g., 64 connections). As a result, a rack 200 that is full of the components 202 may be forced to accommodate a larger number of cables 216 than it was designed to handle, which can lead to several problems.

For example, the large number of cables (e.g., greater than 600) may fill the open spaces 226 that were intended to facilitate the necessary air circulation to allow the components 202 to remain within a desired operating temperature range, as shown in FIG. 9. As a result, users may be forced to keep the front panel 224A (door) open in an effort to prevent the components 202 from overheating. This prevents the components 202 from being secured in the rack 200 and may still fail to provide sufficient cooling of the components 202.

The large number of cables 216 also makes it difficult to feed and route the cables 216 through the cable ports 214, and also to replace and organize the cables. This may lead a user to route the cables 216 through the front of the rack 200, such as through an open front panel 224A, as shown in FIG. 10, resulting in a disorganized tangle of the cables 216 and making the components 202 vulnerable to tampering and theft.

The large number of cables 216 can also increase the likelihood of the cables 216 placing an excessive load on the connections interface 218 and the connectors of the cables 216, such as due to the weight of the cables 216, tangling of the cables 216, resistance during a cable replacement, etc., particularly when the cables 216 are fed through the front opening. This can damage the components 202 and the cables 216, requiring a costly and time-consuming process of replacing the damaged components 202 and cables 216.

Conventional racks 200 can make it difficult to install the cables 216 and connect the cables 216 to the connections interfaces 218 of the components 202. For example, conventional racks 200 may include crossmembers 228, which are shown through the transparent housing panel 224C of FIG. 8, that extend between the vertical frame members 206A. Installation of the cables 216 generally involves routing the cables 216 through the port 214 in the base or plinth 212, behind each of the crossmembers 228 and to the connections interfaces 218 of the components 202. Zip ties may be used to attach the cables 216 to the crossmembers 228.

As a result, the installation of the cables 216 in conventional racks 200 may be difficult and may lead to a disorganized routing of the cables 216, which in turn may lead to damage to the components 202 due to inadequately supported cables 216 and/or inadequate ventilation of the rack chamber 222.

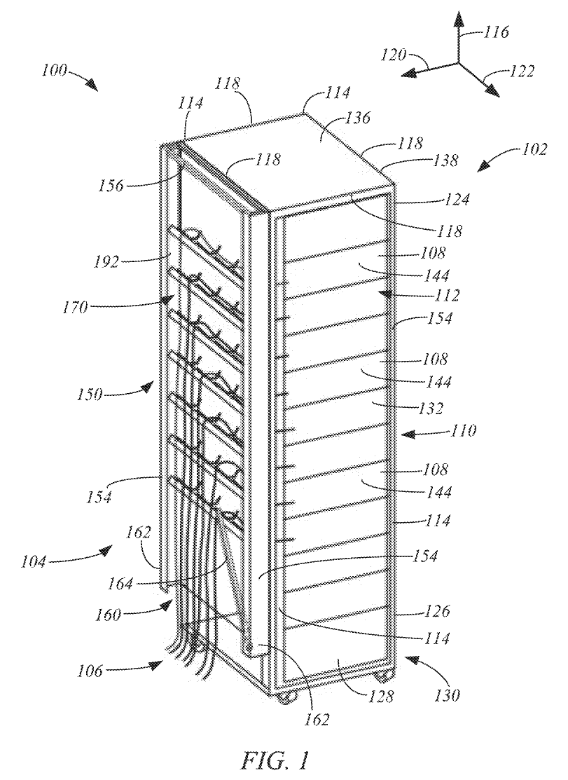

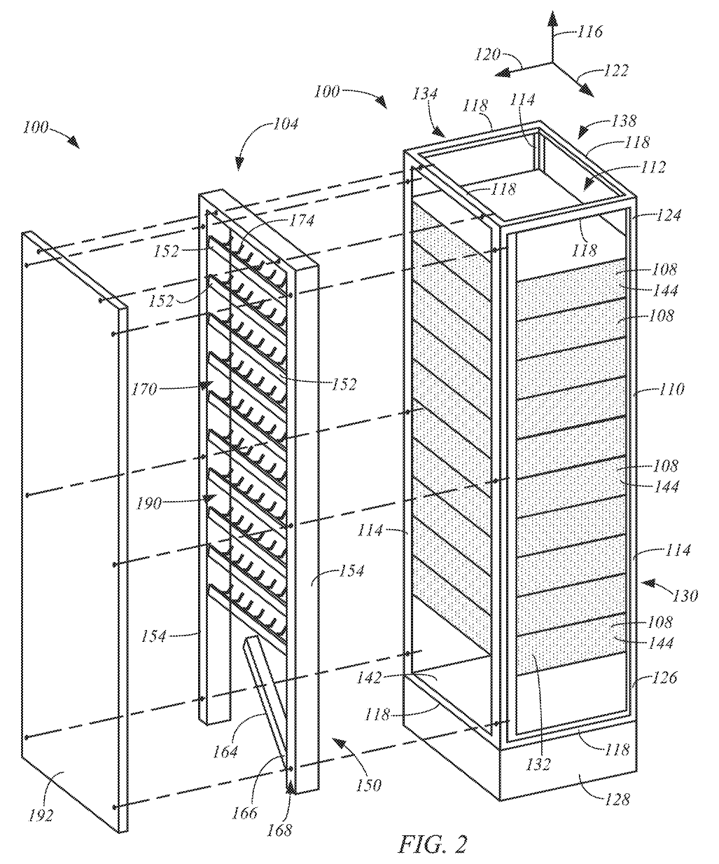

Embodiments of the present disclosure relate to a cable management system that may be used to overcome one or more of the issues described above. FIG. 1 is an isometric view of an example of an electronic equipment housing system 100 that includes an electronic equipment rack 102 and a cable management system 104 that is attached to the rack 102, in accordance with embodiments of the present disclosure. FIG. 2 is a simplified exploded view of the system 100 of FIG. 1, in accordance with embodiments of the present disclosure.

The cable management system 104 generally facilitates improved handling of cables 106 that are connected to electronic components 108 that are supported in the rack 102. The electronic equipment rack 102 may have a conventional design that is similar to the rack 200 described above with reference to FIGS. 8-10. For example, the equipment rack 102 may include a rack frame 110 that is configured to support a plurality of the electronic components 108 in a stacked manner within a rack chamber 112.

The rack frame 110 may include vertical frame members 114 extending along a vertical axis 116. Horizontal frame members 118 extending along a horizontal axis 120 or a horizontal axis 122, which are perpendicular to the vertical axis 116, may connect the vertical frame members 114 to each other at a top side 124 and/or a bottom side 126 of the rack frame 110. The rack frame 110 may be supported on a wheeled base or plinth 128, which may include or replace the one or more of the horizontal frame members 118 at the bottom side 126.

The electronic equipment rack 102 may include a housing 130 that encloses the rack chamber 112 to secure the components 108 and protect the components 108 from environmental conditions (e.g., dust). The housing 130 may include several housing panels that are attached to the rack frame 110, such as a front housing panel 132, a rear housing panel 134, a top housing panel 136, and at least one side panel 138, as shown in FIGS. 1, 2, and FIG. 3, which is a simplified top view of the system 100 of FIGS. 1 and 2 with the top housing panel 136 removed, in accordance with embodiments of the present disclosure. The housing 130 may include a bottom housing panel 142 (FIG. 2) that may be formed by the wheeled base or plinth 128, as indicated in FIG. 1.

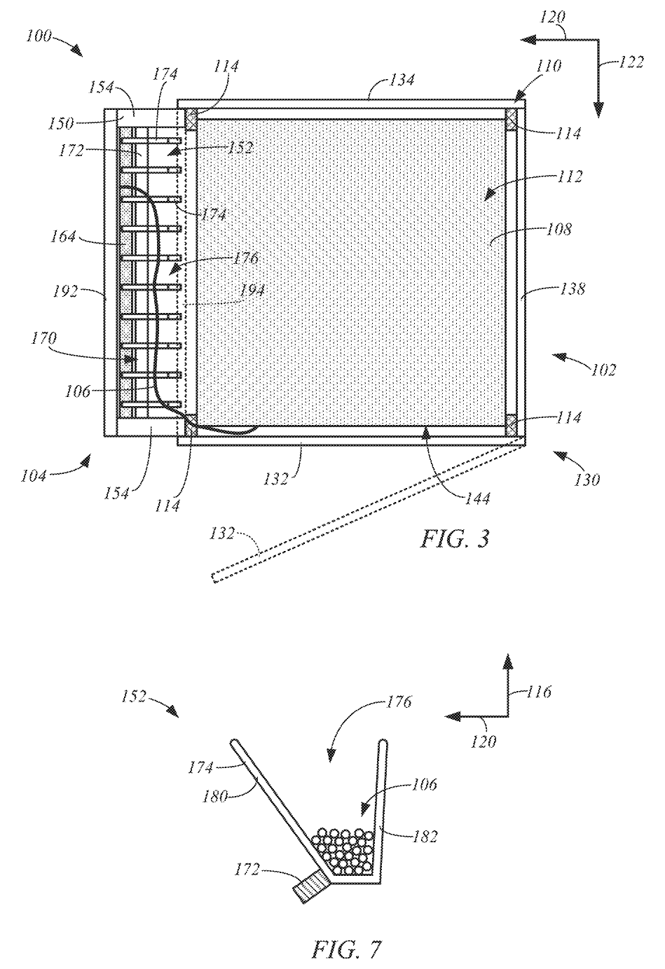

The front housing panel 132 may take the form of a door that is configured to pivot relative to the rack frame 110 to provide access to connection interfaces 144 of the components 102, as indicated in phantom lines in FIG. 3. The front housing panel or door 132 may be lockable to secure the components 108 within the rack chamber 112.

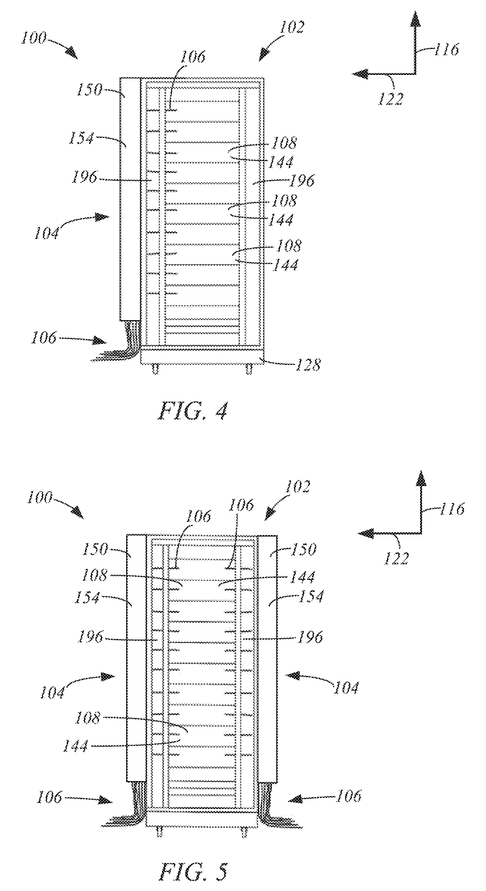

In some embodiments, the cable management system 104 is configured for attachment to the electronic equipment rack 102, such as to a side of the rack frame 110, as shown in FIG. 1 and FIG. 4, which is a simplified front view of the system 100 in accordance with embodiments of the present disclosure. The system 100 may include multiple cable management systems 104 that are attached to the rack 102, such as on opposing sides of the rack 102, as shown in FIG. 5, which is a simplified front view of the system 100, in accordance with embodiments of the present disclosure.

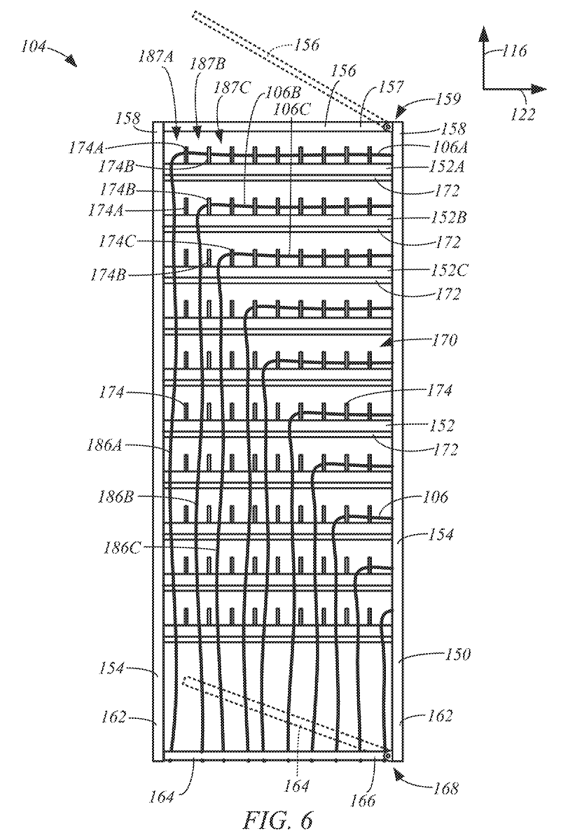

The cable management system 104 includes a cable management frame 150 and a plurality of cable supports 152, as shown in FIGS. 2 and 6, which is a front view of the cable management system 104 in accordance with embodiments of the present disclosure. The frame 150 includes a pair of side vertical members 154 extending along the vertical axis 116. In some embodiments, the frame 150 includes a top horizontal member 156 connected to top ends 158 of the side vertical members 154. In one embodiment, an end 157 of the top member 156 is pivotably attached to the top end 158 of one of the vertical members 154 through a suitable connector 159 (e.g., hinge, etc.), which allows the top member 156 to move between a lowered or raised position (phantom lines) and a horizontal position (solid lines), as shown in FIG. 6.

An opening 160 may be provided at bottom ends 162 of the members 154, through which the cables may be received into the interior of the cable management frame, as shown in FIG. 1. The opening 160 may include a conventional cable gland. The bottom ends 162 may be positioned above the wheeled base 128 along the vertical axis 116.

The frame 150 may include a bottom horizontal member 164 extending between the bottom ends 162 of the side vertical members 154 adjacent the opening 160. In one embodiment, an end 166 of the bottom member 164 is pivotably attached to the bottom end 162 of one of the vertical members 154 through a suitable connector 168 (e.g., hinge, etc.), which allows the bottom member 164 to move between a raised position (phantom lines) and a lowered position (solid lines), as shown in FIG. 6. Positioning the bottom member in the raised position can simplify the installation of the cables 106 into the cable management system 104 or out of the cable management system 104. Once the cables 106 are installed in the cable management system 104, the bottom member 164 may be moved to the lowered position, to secure the cables 106 in place, and possibly may make the frame 150 more rigid.

The cable supports 152 are configured to simplify the support, routing and management of the cables 106 that are connected to the components 108 supported with the equipment rack 102. In one embodiment, the cable supports 152 are connected between the side vertical members 154 within an interior 170 of the cable frame 150 extending between the members 154 and are distributed along the vertical axis 116 between the top and bottom ends 158 and 162.

In some embodiments, one or more of the cable supports 152 may be located along the vertical axis 116 at the same or similar height of a corresponding electronic component 108 supported in the rack frame 102, as shown in FIG. 1. Each cable support 152 may support a set of the cables 106 that are connected to one of the electronic components 108, a portion of a set of cables 106 that are connected to one of the electronic components 108, or a set of the cables 106 that are connected to two of the electronic components 108. While the drawings may illustrate the cable supports 152 supporting a single cable 106 to simplify the illustrations and avoid obscuring the drawings in unnecessary detail, it is understood that the depicted of single cable 106 also represents a set of multiple cables 106 (e.g., more than 20 cables, more than 40 cables, or more than60 cables).

Each cable support 152 includes a horizontal support 172 extending between the side vertical members 154 and a plurality of cable dividers 174 attached to and distributed along the horizontal support 172. In the example cable management system shown in FIG. 6, the horizontal supports 172 extend along the axis 122. Each cable divider may be oriented in a plane that is parallel to the vertical axis 116 and the horizontal axis 120, as shown in FIG. 3.

In some embodiments, the cable dividers 174 have a convex shape, such as shown in FIG. 7, which is a side view of an example of a cable support 152, in accordance with embodiments of the present disclosure. The convex shape of the cable dividers 174 forms a horizontal cable channel 176, in which the cables 106 may be supported, that extends along the axis 122 toward the front side of the equipment rack 102 where the connection interfaces 144 of the components 108 may be located, such as shown in FIGS. 3 and 7. In one embodiment, each cable divider 174 includes a first cable support member 180 extending from the horizontal support 172 away from the equipment rack 102, and a second cable support member 182 extending from the horizontal support 172 toward the equipment rack 102, as shown in FIG. 7.

The dividers 174 may be used to support sections 186 of the sets of the cables 106 extending along the vertical axis 116 between the opening 160 and the corresponding support 152 in vertical cable channels 186 that are distributed along the horizontal axis 122, as shown in FIG. 6. For example, a section 186A of a set of cables 106A supported by the cable support 152A located at the top of the frame 150 may extend vertically in a channel 187A between the side vertical member 154 and the divider 174A of the cable support 152A and of the lower cable supports 152, a section 186B of a set of cables 106B supported by the next lower cable support 152B may extend vertically in a channel 187B between the dividers 174A and the divider 174B of the support 152B and the lower cable supports, a section 186C of a set of cables 106C supported by the next lower cable support 152C may extend in a channel 187C between the divider 174B and the divider 174C of the support 152C and the lower cable supports 152, and so on. This maintains separation of the sections 186 of the sets of cables 106 from the opening 160 to the corresponding electronic component 108 to which they are attached, thereby simplifying the organization of the cables 106.

The weight of the vertical sections 186 of each set of the cables 106 is substantially handled by the corresponding support 152. This allows the cables 106 to be connected to the connections interfaces 144 of the components 108 without any significant tension in the cables 106. As a result, potential damage to the components 108 that may be caused by overly tensioned cables 106 is avoided using the cable management system 104.

During installation of the cable management system 104 to an existing equipment rack 102, a housing panel 194 (phantom lines) of the equipment rack 102 may be removed to expose the rack frame 110, and a cable management frame assembly that includes the cable management frame 150 and the plurality of supports is attached to the exposed rack frame 110, as shown in FIG. 3. This opens the rack chamber 112 to the interior 170 of the cable management frame 150 containing the cable supports 152. Conventional fasteners may be used to attach the cable management frame 150 to the rack frame 110, such as nuts and bolts, screws, etc.

In one embodiment, an exterior side of the cable management frame 150 has an opening 190 to the interior 170 that extends between the side vertical members 154 and the top horizontal member 156, and the cable management system 104 includes a cable management housing panel 192 that is attached to the frame 150 and covers the opening 190, as shown in FIGS. 2 and 3. As a result, the cable management system 104 operates to expand the rack chamber 112 to include the interior 170 of the cable management frame 150.

Additional embodiments relate to the installation of the cable management system 104 on an electronic equipment rack 102 to form the electronic equipment housing system 100. In one embodiment, a housing panel 194 of the rack 102 is removed to expose the rack frame 110, and the cable management frame 150 is attached to the rack frame 110, such as shown in FIG. 3. The housing panel 192 may then be attached to the exterior side of the cable management frame 150 to enclose the interior 170 and the rack chamber 112 and complete the formation of the system 100, such as that shown in FIGS. 1 and 4. In one embodiment, the housing panel 194 of the rack 102 is used as the housing panel 192. This process may be repeated to add additional cable management systems 104 to the rack 102, such as on an opposing side to form the system 100 of FIG. 5, for example.

After installing the components 108 in the rack 102, sets of the cables 106 may be installed by first removing the housing panel 194 from the frame 150 to expose the interior 170. In some embodiments, the bottom member 164 of the cable management frame 150 may be placed in the raised position (phantom lines in FIG. 6) to avoid having to feed the cables through the opening 160.

Ends of a set of the cables 106 for one of the components 108 may be placed in the horizontal cable channel 176 of the cable dividers 174 of one of the supports 152 corresponding to the electronic component 108 (e.g. similar vertical height). Additionally, the set of cables 106 may be positioned in one of the vertical channels 186 (FIG. 6). The ends of the cables 106 may then be routed to the connecting interface 144 of the electronic component 108, such as in the front of the rack 102, and connected to the connecting interface 144, as indicated in FIGS. 1, 3 and 6. This process may be repeated to support other sets of cables 106 for different components 108 in corresponding supports 152 and connecting the cables 106 to the corresponding connecting interfaces 144. Following the installation of the cables 106, the bottom member 164 may be moved to the lowered position (solid lines in FIG. 6). The housing panel 192 may then be attached to the exterior side of the cable management frame 150 to enclose the interior 170 and the rack chamber 112 and complete the installation of the cables 106.

The installation of the housing panel 192 may secure the components 108 within the rack chamber 112 and allow for temperature control of the rack chamber 112. The cable management system allows the sets of cables 106 to be supported outside the rack chamber 112, such as shown in FIGS. 3, 4 and 5. Thus, unlike the airflow channel 226 of the conventional equipment rack 200 shown in FIGS. 9 and 10, airflow channels 196 of the rack chamber 112 can remain free of the cables 106, as shown in FIGS. 4 and 5. Accordingly, the air circulation problems caused by cables blocking airflow pathways within the rack chamber of the equipment racks 200 of the prior art are avoided.

Although the embodiments of the present disclosure have been described with reference to preferred embodiments, workers skilled in the art will recognize that changes may be made in form and detail without departing from the spirit and scope of the present disclosure.

What is claimed is:

1. A cable management system configured for attachment to a rack frame of an electronic equipment rack, the cable management system comprising:a cable management frame including a pair of side vertical frame members extending along a vertical axis and a top horizontal member connected to top ends of the of the side vertical members;a plurality of cable supports connected between the side vertical members and distributed from each other along the vertical axis between the top ends and bottom ends of the side vertical members, each cable support including a horizontal support extending between the side vertical members and a plurality of cable dividers attached to and distributed along the horizontal support; and a cable management housing panel attached to the cable management frame and covering an opening to a cable management chamber extending between the side vertical members and containing the cable supports.

2. The cable management system according to claim 1, wherein the cable management frame includes a bottom member extending between the bottom ends of the side vertical members.

3. The cable management system according to claim 1, wherein the top member is pivotably attached to one of the side vertical members and/or the bottom member is pivotably attached to one of the side vertical members.

4. The cable management system according to claim 1, wherein opposing ends of each horizontal support are attached to one of the side vertical members.

5. The cable management system according to claim 4, wherein each cable divider has a convex shape and is oriented in a plane that is parallel to the vertical axis.

6. The cable management system according to claim 5, wherein each cable divider comprises:a first cable support member extending from the horizontal support toward the panel;and a second cable support member extending from the horizontal support away from the panel.

7. An electronic equipment housing system comprising:an electronic equipment rack including a rack frame configured to support a plurality of rack-mountable electronic devices in a stacked relationship along a vertical axis within a rack chamber;a cable management system comprising:a cable management frame attached to the rack frame, the cable management frame including a pair of side vertical members extending along the vertical axis and a top horizontal member connected to top ends of the of the side vertical members;a plurality of cable supports connected between the side vertical members and distributed from each other along the vertical axis between the top ends and bottom ends of the side vertical members, each cable support including a horizontal support extending between the side vertical members and a plurality of cable dividers attached to and distributed along the horizontal support; anda cable management housing panel attached to the cable management frame and covering an opening to a cable management chamber extending between the side vertical members and containing the cable supports.

8. The electronic equipment housing system according to claim 7, wherein:
the rack frame includes a plurality of vertical frame members extending along the vertical axis within the rack chamber; anda plurality of housing panels attached to the rack frame including:a front housing panel covering a front side of the rack chamber;a rear housing panel covering a rear side of the rack chamber that is opposite the front side;a top housing panel covering a top side of the rack chamber and extending between the front and rear housing panels;a bottom housing panel covering a bottom side of the rack chamber that is opposite the top side and extending between the front and rear housing panels; anda side housing panel covering a first side of the rack chamber and extending between the front, rear, top and bottom housing panels.

9. The electronic equipment housing system according to claim 8, wherein the cable management frame is attached to the rack frame on a second side of the rack chamber that is opposite the first side.

10. The electronic equipment housing system according to claim 9, wherein the cable management frame extends between the front, rear, top and bottom housing panels.

11. The electronic equipment housing system according to claim 9, wherein:the electronic equipment rack includes a wheeled base supporting the rack frame; andthe bottom ends of the side vertical members are positioned above the wheeled base along the vertical axis.

12. The electronic equipment housing system according to claim 10, wherein the front housing panel is configured to pivot relative to the rack frame.

13. The electronic equipment housing system according to claim 8, wherein the cable management frame includes a bottom member extending between the bottom ends of the side vertical members.

14. The electronic equipment housing system according to claim 13, wherein the top member is pivotably attached to one of the side vertical members and/or the bottom member is pivotably attached to one of the side vertical members.

15. The electronic equipment housing system according to claim 8 wherein:
opposing ends of each horizontal support are attached to one of the side vertical members; andeach cable divider has a convex shape and is oriented in a plane that is parallel to the vertical axis.

16. The electronic equipment housing system according to claim 15, wherein each cable divider comprises:a first cable support member extending from the horizontal support toward the panel;and a second cable support member extending from the horizontal support away from the panel.

17. A method of installing a cable management system to an electronic equipment rack, wherein:the electronic equipment rack includes a rack frame configured to support a plurality of rack-mountable electronic devices in a stacked relationship along a vertical axis within a rack chamber; and the method comprising:attaching a cable management frame assembly of the cable management system to the rack frame, the cable management frame assembly including:
a cable management frame comprising a pair of side vertical members extending along the vertical axis and a top horizontal member connected to top ends of the side vertical members; and a plurality of cable supports connected between the side vertical members and distributed from each other along the vertical axis between the top ends and bottom ends of the side vertical members, each cable support including a horizontal support extending between the side vertical members and a plurality of cable dividers attached to and distributed along the horizontal support; and covering an opening to an interior of the cable management frame extending between the side vertical members and containing the cable supports comprising attaching a cable management housing panel to the cable management frame.

18. The method according to claim 17, wherein:the electronic equipment rack includes:a plurality of vertical frame members extending along the vertical axis within the rack chamber; anda plurality of housing panels attached to the rack frame including:a front housing panel covering a front side of the rack chamber;a rear housing panel covering a rear side of the rack chamber that is opposite the front side;a top housing panel covering a top side of the rack chamber and extending between the front and rear housing panels;a bottom housing panel covering a bottom side of the rack chamber that is opposite the top side and extending between the front and rear housing panels; and
a first side housing panel covering a first side of the rack chamber and extending between the front, rear, top and bottom housing panels; and attaching the cable management frame assembly to the rack frame comprises attaching the cable management frame assembly to the rack frame on a second side of the rack chamber that is opposite the first side.

19. The method according to claim 18, including:supporting with the rack frame a plurality of electronic devices in a stacked manner along the vertical axis within the rack chamber; androuting each of a plurality of cables to one of the electronic devices along a vertical cable channel extending along the vertical axis between pairs of the cable dividers of a plurality of the cable supports and along a horizontal cable channel over a plurality of the cable dividers of one of the cable supports to the electronic device.

20. The method according to claim 18, wherein attaching the cable management frame assembly to the rack frame comprises:removing a second side housing panel covering the second side of the rack chamber and extending between the front, rear, top and bottom housing panels; andattaching the cable management frame assembly to the rack frame on the second side of the rack chamber.
